(19) United States
(12) Patent Application Publication
(10) Pub. No.: US 2025/0293023 A1
(43) Pub. Date: Sep. 18, 2025

(54) SILICON CARBIDE WAFER MANUFACTURING METHOD

(71) Applicant: Hon Young Semiconductor Corporation, Hsinchu City (TW)

(72) Inventors: Chin-Hung CHEN, Hsinchu City (TW); Hung-Hsin YEN, Hsinchu City (TW)

(21) Appl. No.: 18/633,550

(22) Filed: Apr. 12, 2024

(30) Foreign Application Priority Data
Mar. 14, 2024 (TW) 113109545

(51) Int. Cl. H01L 21/02; H01L 21/321; H01L 21/762; H01L 21/78

(52) U.S. Cl. CPC H01L 21/02529; H01L 21/02378; H01L 21/02598; H01L 21/02694; H01L 21/3212; H01L 21/7813; H01L 21/76254

(57) ABSTRACT

A method for manufacturing silicon carbide wafers includes the following steps. A silicon carbide epitaxial layer is formed on a first silicon carbide substrate. An ion implantation process is used to form a thermal separation layer in the silicon carbide epitaxial layer. A temporary substrate is used to bond the silicon carbide epitaxial layer. Heating causes the thermal separation layer to decompose, and the silicon carbide epitaxial layer is divided into an upper silicon carbide epitaxial layer and a lower silicon carbide epitaxial layer. A chemical mechanical polishing process is performed on the upper silicon carbide epitaxial layer bonded to the temporary substrate.

### CROSS-REFERENCE TO RELATED APPLICATION

This application claims priority to Taiwan Application Serial Number 113109545, filed Mar. 14, 2024, which is herein incorporated by reference in its entirety.

### BACKGROUND

### Field of Disclosure

The present disclosure relates to a semiconductor manufacturing method, and more particularly to a silicon carbide wafer manufacturing method.

### Description of Related Art

A silicon carbide wafer is a substrate used in the field of semiconductor manufacturing. This material has superior properties that are ideal for high temperature, high voltage and high frequency applications. The manufacturing process of silicon carbide wafers involves growing silicon carbide single crystals to a specific size and thickness and then forming them into disc-shaped wafers for use in making semiconductor devices.

One of the main advantages of silicon carbide materials is its high thermal stability. Silicon carbide's ability to remain stable under extreme temperature conditions makes it excellent in high-temperature applications. In addition, silicon carbide also has a high electron drift rate, which means that electrons move faster in the crystal, thereby improving the overall performance of the device.

Silicon carbide wafers also perform well in high power and high frequency applications. It has superior electrical conductivity and heat dissipation properties, making it ideal for manufacturing power electronic devices such as high-power converters and power transmission circuits. At the same time, silicon carbide also shows excellent performance in radio frequency (RF) applications, making it the first choice for manufacturing high-frequency wireless communication devices.

In the manufacturing technology of silicon carbide wafers, it is necessary to transplant the silicon carbide epitaxial layer generated by a wafer substrate to another substrate surface. However, there are some problems after the silicon carbide epitaxial layer is bonded to another substrate. This will result in loss of subsequent process yield and increased difficulty in defect measurement.

### SUMMARY

The present disclosure provides silicon carbide wafer manufacturing methods to deal with the needs of the prior art problems.

In one or more embodiments, a silicon carbide wafer manufacturing method including: forming a silicon carbide epitaxial layer on a first silicon carbide substrate; using an ion implantation process to form a thermal separation layer in the silicon carbide epitaxial layer; using a temporary substrate to bond the silicon carbide epitaxial layer; heating the silicon carbide epitaxial layer causes the thermal separation layer to decompose and the silicon carbide epitaxial layer is separated into an upper silicon carbide epitaxial layer and a lower silicon carbide epitaxial layer; and performing a first chemical mechanical polishing process on the upper silicon carbide epitaxial layer bonded to the temporary substrate.

In one or more embodiments, a silicon carbide wafer manufacturing method including: forming a silicon carbide epitaxial layer on a first silicon carbide substrate; using an ion implantation process to form a thermal separation layer in the silicon carbide epitaxial layer; using a temporary substrate to bond the silicon carbide epitaxial layer; heating the silicon carbide epitaxial layer causes the thermal separation layer to decompose and the silicon carbide epitaxial layer is separated into an upper silicon carbide epitaxial layer and a lower silicon carbide epitaxial layer; performing a first chemical mechanical polishing process on the upper silicon carbide epitaxial layer bonded to the temporary substrate; and bonding a second silicon carbide substrate to a surface of the upper silicon carbide epitaxial layer that is processed by the first chemical mechanical polishing process.

In one or more embodiments, a silicon carbide wafer manufacturing method including: forming a silicon carbide epitaxial layer on a first silicon carbide substrate; using an ion implantation process to form a thermal separation layer in the silicon carbide epitaxial layer; using a temporary substrate to bond the silicon carbide epitaxial layer; heating the silicon carbide epitaxial layer causes the thermal separation layer to decompose and the silicon carbide epitaxial layer is separated into an upper silicon carbide epitaxial layer and a lower silicon carbide epitaxial layer; performing a first chemical mechanical polishing process on the upper silicon carbide epitaxial layer bonded to the temporary substrate; bonding a second silicon carbide substrate to a surface of the upper silicon carbide epitaxial layer that is processed by the first chemical mechanical polishing process; and removing the temporary substrate and performing a second chemical mechanical polishing process on an exposed surface of the upper silicon carbide epitaxial layer.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIGS. 1A and 1B illustrate cross-sectional views of several steps of a silicon carbide wafer manufacturing method according to some embodiments of the present disclosure; and

FIG. 2 illustrates a flowchart of several steps of a silicon carbide wafer manufacturing method according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

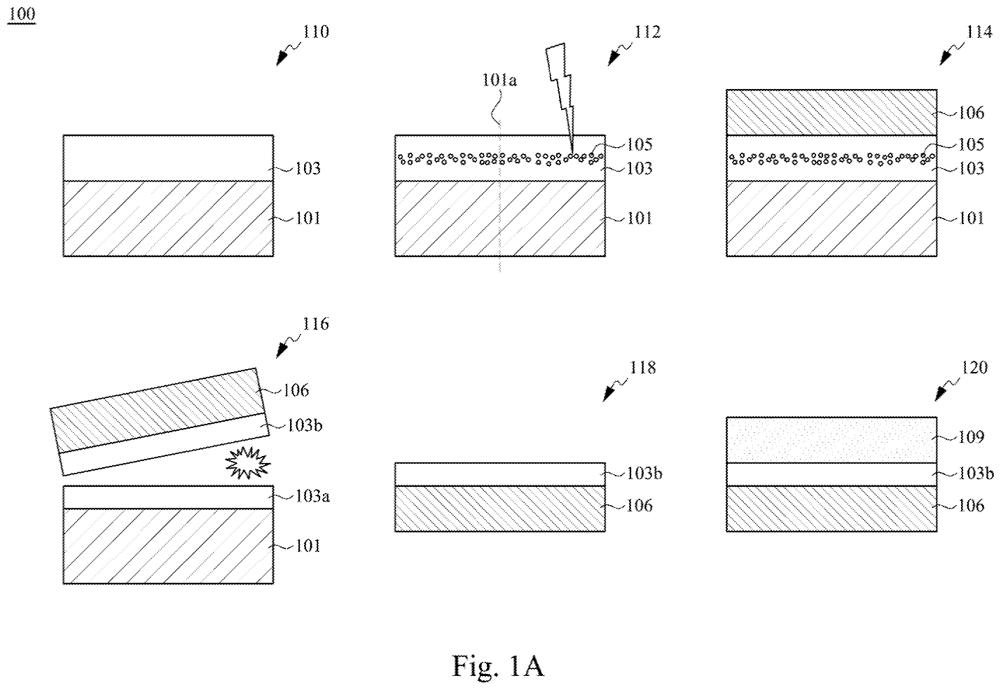

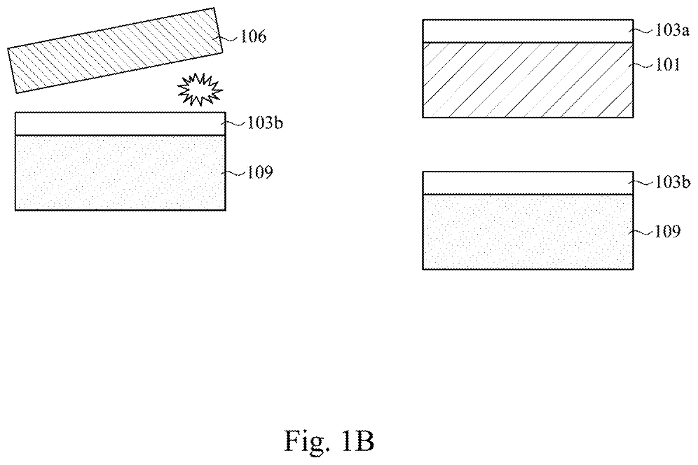

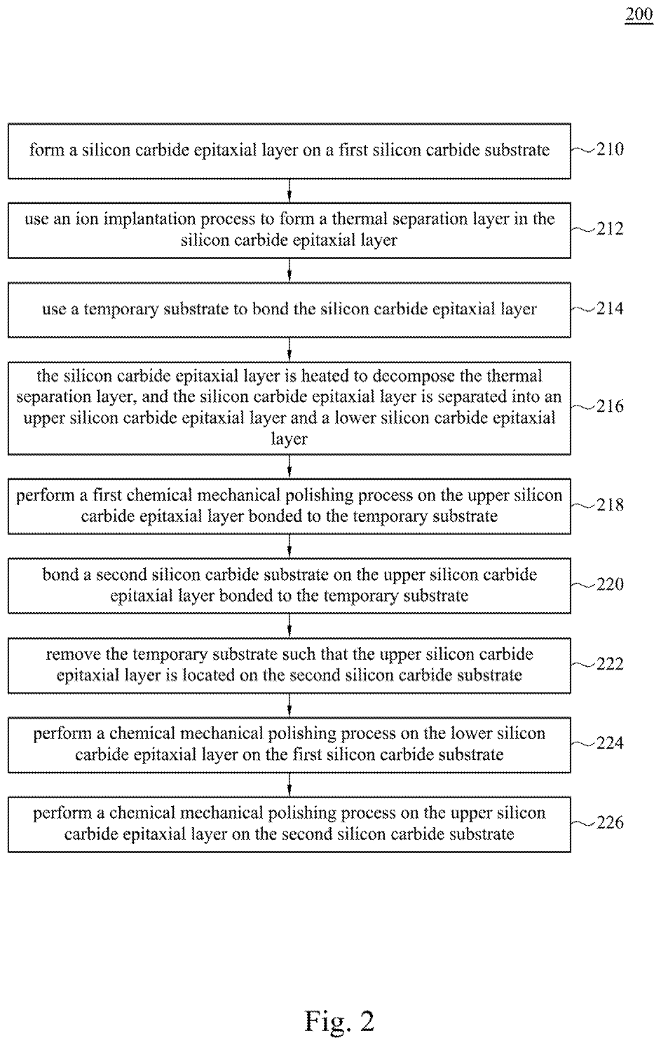

Reference is made to FIGS. 1A, 1B and 2. FIGS. 1A and 1B illustrate cross-sectional views of several steps of a silicon carbide wafer manufacturing method 100 according to some embodiments of the present disclosure, and FIG. 2 illustrates a flowchart of several steps of a silicon carbide wafer manufacturing method 200 according to some embodiments of the present disclosure. In order to solve the problem that transplanting the silicon carbide epitaxial layer to another substrate may cause a loss in subsequent process yield and increase the difficulty in defect measurement, the present invention proposes an improved silicon carbide wafer manufacturing method.

In step 110 of FIG. 1A and step 210 of FIG. 2, a silicon carbide epitaxial layer 103 is formed on a first silicon carbide substrate 101. A silicon carbide wafer is a semiconductor wafer made from silicon carbide material and is commonly used to manufacture components for high-power, high-frequency applications such as power amplifiers and radio frequency components. The method of forming the silicon carbide epitaxial layer involves techniques such as chemical vapor deposition (CVD) or physical vapor deposition (PVD). In some embodiments of the present invention, the silicon carbide epitaxial layer 103 is a single-crystal silicon carbide epitaxial layer. The silicon carbide epitaxial layer 103 can generally be divided into two types: single crystal and polycrystalline. The single-crystal epitaxial layer has a relatively complete crystal structure and provides better electrical properties, especially in high-temperature and high-power applications. In high-power, high-frequency applications, the performance of single-crystal silicon carbide may be even more critical.

In the silicon carbide wafer manufacturing process, a common method is to use chemical vapor deposition. This method includes the following steps.

Pretreatment: clean the wafer surface to ensure that it is dust-free and free of impurities.

Introduction of precursor gas: in a high vacuum or nitrogen environment, the precursor gas of silicon carbide (such as methylsilane, dimethylsilyl ether) is introduced into a reaction chamber.

Depositing silicon carbide thin film: the precursor gas is decomposed and deposited on the wafer surface to form a silicon carbide thin film. This step is usually performed at high temperatures to promote the reaction.

Epitaxial growth: the introduction of precursor gas and film deposition are repeated to gradually form a silicon carbide epitaxial layer. Control reaction conditions such as temperature and gas flow to ensure the uniformity and thickness of the epitaxial layer.

Physical vapor deposition can also be used for the preparation of silicon carbide films, in which a solid source material or target material is used to form a gas phase by exciting the source material and then deposited on the wafer surface.

The manufacturing of silicon carbide wafers involves previously processing the wafer, and then using techniques such as CVD or PVD to deposit a silicon carbide film, and finally form a silicon carbide epitaxial layer.

In step 112 of FIG. 1A and step 212 of FIG. 2, an ion implantation process is used to form a thermal separation layer 105 in the silicon carbide epitaxial layer 103. In some embodiments of the present invention, an extension direction of the thermal separation layer 105 is perpendicular to a central axis 101a of the first silicon carbide substrate 101 (e.g., a central axis of a disc-shaped silicon carbide substrate). In some embodiments of the present invention, a dose range of ion value is 1E15˜5E17 [atom/cm²]. Using an ion implantation process to form a thermal separation layer in a silicon carbide epitaxial layer is a technology that changes the properties of the material. Hydrogen ions (H⁺), helium ions (He⁺) or their combinations are usually used. The following is an exemplary process.

Prepare the silicon carbide epitaxial layer: ensure that the silicon carbide epitaxial layer has grown on the wafer and is of the required thickness and quality.

Select ion species: select the appropriate ion species according to the characteristics of the thermal separation layer to be formed.

Energy and dose control: adjust the energy and dose of ion implantation. Energy control affects the penetration depth of ions, while dose affects the density of implanted ions. Adjustment of these parameters will affect the depth and nature of the thermal segmentation layer formed.

Ion implantation process: under specific vacuum conditions, selected ions are implanted into the silicon carbide epitaxial layer to form a thermal separation layer.

Heat treatment: after completing the ion implantation, heat treatment is performed to repair the crystal lattice and stabilize the weakened area. This helps ensure the stability of the formed thermal separation layer in subsequent processes.

In step 114 of FIG. 1A and step 214 of FIG. 2, a temporary substrate 106 is used to bond the silicon carbide epitaxial layer 103. This step facilitates the subsequent division of the silicon carbide epitaxial layer 103 and allows the divided half of the silicon carbide epitaxial layer to be easily transferred to another silicon carbide substrate.

In step 116 of FIG. 1A and step 216 of FIG. 2, heating causes the thermal separation layer 105 to decompose, and the silicon carbide epitaxial layer 103 is separated or divided into an upper silicon carbide epitaxial layer 103b and a lower silicon carbide epitaxial layer 103a.

In step 118 of FIG. 1A and step 218 of FIG. 2, a chemical mechanical polishing process is performed on the upper silicon carbide epitaxial layer 103b bonded to the temporary substrate 106. This chemical mechanical polishing (hereinafter referred to as CMP) process is used to improve the smoothness and processing accuracy of the separated surface of the silicon carbide epitaxial layer 103b, and to remove possible defects or damage caused by the decomposition of the thermal separation layer 105. The following are some Example steps.

Prepare CMP process machine: set up the CMP process machine, including appropriate parameters such as abrasives, grinding wheels, grinding wheel speed and pressure control.

Coarse grinding stage: start using larger particle abrasives for coarse grinding to quickly remove uneven surface areas.

Medium grinding stage: switch to smaller particle abrasives and perform medium grinding to gradually reduce the roughness of the surface and achieve higher flatness.

Fine grinding stage: use finer abrasives for fine grinding to further improve surface smoothness and processing accuracy.

Cleaning and inspection: after completing the CMP process, clean to remove residual abrasives and contaminants, and then inspect the processed upper silicon carbide epitaxial layer.

In step 120 of FIG. 1A and step 220 of FIG. 2, a second silicon carbide substrate 109 is further bonded to the upper silicon carbide epitaxial layer 103b that is bonded to the temporary substrate 106. The second silicon carbide substrate 109 is bonded to a surface of the upper silicon carbide epitaxial layer 103b that has been processed by the chemical mechanical polishing process. The temporary substrate 106 and the second silicon carbide substrate 109 are located on two opposite sides (or surfaces) of the upper silicon carbide epitaxial layer respectively. In some embodiments of the present invention, the second silicon carbide substrate 109 and the first silicon carbide substrate 101 are made of the same material.

In step 122 of FIG. 1B and step 222 of FIG. 2, the temporary substrate 106 is removed so that the upper silicon carbide epitaxial layer 103b is located on (and in contact with) the second silicon carbide substrate 109. The temporary substrate 106 may be removed in the following manner.

Chemical wet etching: using specific chemical solutions that can selectively erode the temporary substrate without damaging the upper silicon carbide epitaxial layer. For example, selective wet etching of silicon or other substrate materials. This requires careful selection of chemical solutions to ensure that only the temporary substrate is removed without affecting the overlying silicon carbide.

Mechanical peeling: using mechanical force to separate the temporary substrate. This may include the application of mechanical impact or stress to peel off the substrate. This requires careful control of the direction and magnitude of the force to avoid damaging the silicon carbide epitaxial layer.

Heat treatment: by high-temperature treatment, the temporary substrate material generates specific thermal expansion characteristics, thereby assisting separation. This method is often combined with chemical wet etching for added effectiveness.

Laser peeling: use a laser beam to focus on the temporary substrate, which will generate heat in the light absorption area and facilitate peeling. Such a process also requires careful energy and time control.

Ion implantation: The properties of the temporary substrate material are changed through the ion implantation process to make it easy to peel off.

When these methods are performed, special attention needs to be paid to selecting appropriate parameters to ensure effective and controlled removal of the temporary substrate while protecting the integrity of the upper silicon carbide epitaxial layer.

In step 124 of FIG. 1B and step 224 of FIG. 2, a chemical mechanical polishing process is performed on the lower silicon carbide epitaxial layer 103a on the first silicon carbide substrate 101. In step 124 in FIG. 1B and step 226 in FIG. 2, a chemical mechanical polishing process is performed on the upper silicon carbide epitaxial layer 103b on the second silicon carbide substrate 109. Steps 224 and 226 may be performed simultaneously or separately. The chemical mechanical polishing process removes the damaged layers of the lower silicon carbide epitaxial layer 103a and the upper silicon carbide epitaxial layer 103b to restore the surface of the epitaxial layer to a flat state, thereby obtaining two silicon carbide wafers. In the chemical these mechanical polishing processes, two opposite surfaces of the upper silicon carbide epitaxial layer 103b were subjected to a chemical mechanical polishing process respectively to deal with the problems of bonding flatness, new defects on the surface of the bonded silicon carbide substrate, and uneven surfaces of the silicon carbide epitaxial layers.

In sum, the silicon carbide wafer manufacturing method disclosed herein utilizes epitaxy technology to grow a thicker, high-quality silicon carbide epitaxial layer, and uses wafer separation technology to implant a high dose of H⁺ or He⁺ into the silicon carbide wafer by an ion implantation process. The silicon carbide wafer is bonded to the temporary substrate, and the temporary substrate with the silicon carbide epitaxial layer is peeled off through heating. After the silicon carbide epitaxial layer on the temporary substrate is peeled off, it is transferred to a permanent silicon carbide substrate. The silicon carbide substrate and the original silicon carbide wafer are processed to remove the damaged layer and restore the surface of the epitaxial layer to a flat state by CMP processes. Finally, two silicon carbide wafers with high-quality epitaxial layers can be obtained.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A silicon carbide wafer manufacturing method comprising:
forming a silicon carbide epitaxial layer on a first silicon carbide substrate;
using an ion implantation process to form a thermal separation layer in the silicon carbide epitaxial layer;
using a temporary substrate to bond the silicon carbide epitaxial layer;
heating the silicon carbide epitaxial layer causes the thermal separation layer to decompose and the silicon carbide epitaxial layer is separated into an upper silicon carbide epitaxial layer and a lower silicon carbide epitaxial layer; and
performing a first chemical mechanical polishing process on the upper silicon carbide epitaxial layer bonded to the temporary substrate.

2. The method of claim 1, wherein ions used in the ion implantation process comprise hydrogen ions.

3. The method of claim 1, wherein ions used in the ion implantation process comprise helium ions.

4. The method of claim 1, wherein the silicon carbide epitaxial layer is a single-crystal silicon carbide epitaxial layer.

5. The method of claim 1, wherein an extension direction of the thermal separation layer is perpendicular to a central axis of the first silicon carbide substrate.

6. The method of claim 1 further comprising: bonding a second silicon carbide substrate on the upper silicon carbide epitaxial layer bonded to the temporary substrate, wherein the temporary substrate and the second silicon carbide substrate are located on two opposite sides of the upper silicon carbide epitaxial layer.

7. The method of claim 6 further comprising: removing the temporary substrate such that the upper silicon carbide epitaxial layer is located on the second silicon carbide substrate.

8. The method of claim 7 further comprising: performing a second chemical mechanical polishing process on the upper silicon carbide epitaxial layer bonded to the second silicon carbide substrate.

9. The method of claim 1 further comprising: performing a second chemical mechanical polishing process on the lower silicon carbide epitaxial layer bonded to the first silicon carbide substrate.

10. A silicon carbide wafer manufacturing method comprising:
forming a silicon carbide epitaxial layer on a first silicon carbide substrate;
using an ion implantation process to form a thermal separation layer in the silicon carbide epitaxial layer;
using a temporary substrate to bond the silicon carbide epitaxial layer;
heating the silicon carbide epitaxial layer causes the thermal separation layer to decompose and the silicon carbide epitaxial layer is separated into an upper silicon carbide epitaxial layer and a lower silicon carbide epitaxial layer;
performing a first chemical mechanical polishing process on the upper silicon carbide epitaxial layer bonded to the temporary substrate; and
bonding a second silicon carbide substrate to a surface of the upper silicon carbide epitaxial layer that is processed by the first chemical mechanical polishing process.

11. The method of claim 10, wherein the temporary substrate and the second silicon carbide substrate are located on two opposite sides of the upper silicon carbide epitaxial layer.

12. The method of claim 10, wherein ions used in the ion implantation process comprise hydrogen ions, helium ions or a combination thereof.

13. The method of claim 10, wherein the silicon carbide epitaxial layer is a single-crystal silicon carbide epitaxial layer.

14. The method of claim 10, wherein an extension direction of the thermal separation layer is perpendicular to a central axis of the first silicon carbide substrate.

15. The method of claim 10 further comprising: removing the temporary substrate such that the upper silicon carbide epitaxial layer is located on the second silicon carbide substrate.

16. A silicon carbide wafer manufacturing method comprising:
forming a silicon carbide epitaxial layer on a first silicon carbide substrate;
using an ion implantation process to form a thermal separation layer in the silicon carbide epitaxial layer;
using a temporary substrate to bond the silicon carbide epitaxial layer;
heating the silicon carbide epitaxial layer causes the thermal separation layer to decompose and the silicon carbide epitaxial layer is separated into an upper silicon carbide epitaxial layer and a lower silicon carbide epitaxial layer;
performing a first chemical mechanical polishing process on the upper silicon carbide epitaxial layer bonded to the temporary substrate;
bonding a second silicon carbide substrate to a surface of the upper silicon carbide epitaxial layer that is processed by the first chemical mechanical polishing process; and
removing the temporary substrate and performing a second chemical mechanical polishing process on an exposed surface of the upper silicon carbide epitaxial layer.

17. The method of claim 16, wherein ions used in the ion implantation process comprise hydrogen ions, helium ions or a combination thereof.

18. The method of claim 16, wherein the silicon carbide epitaxial layer is a single-crystal silicon carbide epitaxial layer.

19. The method of claim 16, wherein an extension direction of the thermal separation layer is perpendicular to a central axis of the first silicon carbide substrate.

20. The method of claim 16 further comprising: performing a third chemical mechanical polishing process on the lower silicon carbide epitaxial layer bonded to the first silicon carbide substrate.
